(19) United States
(12) Patent Application Publication
(10) Pub. No.: US 2025/0098165 A1
(43) Pub. Date: Mar. 20, 2025

(54) SEMICONDUCTOR MEMORY DEVICE

(71) Applicant: Kioxia Corporation, Tokyo (JP)

(72) Inventors: Fumie KIKUSHIMA, Yokkaichi Mie (JP); Michiko ISHIDA, Yokkaichi Mie (JP); Yosuke MURAKAMI, Mie Mie (JP); Hideomi AOIKE, Tsu Mie (JP); Tatsuya ISHIKAWA, Yokkaichi Mie (JP); Ryo YOUGAUCHI, Yokkaichi Mie (JP); Tatsuo OGURA, Yokkaichi Mie (JP)

(21) Appl. No.: 18/884,125

(22) Filed: Sep. 13, 2024

(30) Foreign Application Priority Data
Sep. 20, 2023 (JP) 2023-152639

(51) Int. Cl. H10B 43/27; H10B 43/10

(52) U.S. Cl. CPC H10B 43/27; H10B 43/10

(57) ABSTRACT

In one embodiment, a semiconductor memory device includes a stacked body of a first conductive films and first insulation films alternately stacked with each other in a first direction. A plurality of columnar bodies is in the stacked body. Each columnar body includes a first semiconductor part extending in the first direction, a first insulation part between the first semiconductor part and the stacked body, a second insulation part between the first insulation part and the stacked body, third insulation parts between the second insulation part and the first conductive films, and fourth insulation parts between the second insulation part and the first insulation films. Each second insulation part has first portions between the first insulation part and the first conductive films and second portions between the first insulation part and the first insulation film. The second portions are thinner than the first portions in a second direction.

### CROSS-REFERENCE TO RELATED APPLICATIONS

This application is based upon and claims the benefit of priority from Japanese Patent Application No. 2023-152639, filed Sep. 20, 2023, the entire contents of which are incorporated herein by reference.

### FIELD

Embodiments described herein relate generally to a semiconductor memory device.

### BACKGROUND

A semiconductor memory device, such as a NAND flash memory, may include a three-dimensional memory cell array in which a plurality of memory cells are three-dimensionally arranged. In such a three-dimensional memory cell array, there may be a problem in that electrical charge leaks between adjacent memory cells that share a charge trapping film.

### BRIEF DESCRIPTION OF THE DRAWINGS

FIG. 1 is a cross-sectional view of a semiconductor memory device according to a first embodiment.

FIG. 2 is a schematic plan view of a stacked body.

FIG. 3 is a schematic cross-sectional view a memory cell array.

FIG. 4 is a cross-sectional view taken along the line 4-4 in FIG. 3.

FIG. 5 is a cross-sectional view taken along the line 5-5 in FIG. 3.

FIG. 6 is a cross-sectional view of a portion indicated by a dashed box in FIG. 3 in an enlarged manner.

FIG. 7 is a schematic cross-sectional view of a memory cell array according to a second embodiment.

FIG. 8 is a schematic cross-sectional view of a memory cell array according to a third embodiment.

FIG. 9 is a schematic cross-sectional view of a memory cell array according to a fourth embodiment.

FIG. 10 is a schematic cross-sectional view of a memory cell array according to a fifth embodiment.

FIG. 11 is a schematic cross-sectional view of a memory cell array according to a sixth embodiment.

FIG. 12 is a schematic cross-sectional view of a memory cell array according to a seventh embodiment.

FIG. 13 is a schematic cross-sectional view of a staircase portion of a memory cell array according to an eighth embodiment.

FIGS. 14 to 20 are cross-sectional views for illustrating aspects of an example of a method for producing a semiconductor memory device according to the first embodiment.

FIG. 21 is a cross-sectional view illustrating aspects of a method for producing a semiconductor memory device according to the sixth embodiment.

FIG. 22 is a schematic cross-sectional view of a memory cell array according to a ninth embodiment.

FIG. 23 is a schematic cross-sectional view of a memory cell array according to a tenth embodiment.

FIGS. 24 to 28 are cross-sectional views for illustrating aspects of a method for producing a semiconductor memory device according to the ninth embodiment.

FIG. 29 is a schematic cross-sectional view of a memory cell array according to an eleventh embodiment.

FIG. 30 is a cross-sectional view illustrating aspects of a lower end portion of a columnar body according to the first embodiment.

FIG. 31 is a cross-sectional view illustrating aspects of another lower end portion of a columnar body.

FIG. 32 is a cross-sectional view illustrating aspects of still another lower end portion of a columnar body.

FIG. 33 is a cross-sectional view illustrating a configuration example of a lower end portion of a columnar body is applied to the ninth embodiment.

FIG. 34 is a cross-sectional view illustrating a configuration example of another lower end portion of a columnar body is applied to the ninth embodiment.

FIG. 35 is a cross-sectional view illustrating a configuration example of still another lower end portion of columnar body is applied to the ninth embodiment.

### DETAILED DESCRIPTION

An object of the present invention is to provide a semiconductor memory device that inhibits electric charge from leaking between memory cells and thus can have reduced memory cell sizes.

In general, according to one embodiment, a semiconductor memory device includes a stacked body that includes a plurality of first conductive films and a plurality of first insulation films alternately stacked in a first direction. A plurality of first columnar bodies each include a first semiconductor part extending in the first direction in the stacked body, a first insulation part provided between the first semiconductor part and the stacked body, a second insulation part provided between the first insulation part and the stacked body, third insulation parts provided between the second insulation part and the plurality of first conductive films, and fourth insulation parts provided between the second insulation part and the plurality of first insulation films. Each second insulation part has first portions provided between the first insulation part and the first conductive films and second portions provided between the first insulation part and the first insulation films, the second portions being thinner than the first portions in a second direction that is perpendicular to the first direction. In some examples, the first insulation films are each a layered film comprising a second insulation film and a third insulation film.

Certain example embodiments according to the present disclosure will be described with reference to the drawings. These embodiments are not intended to limit the present disclosure. Furthermore, the drawings are schematic or conceptual. In the description and drawings, the same components or aspects are denoted by the same reference characters.

### First Embodiment

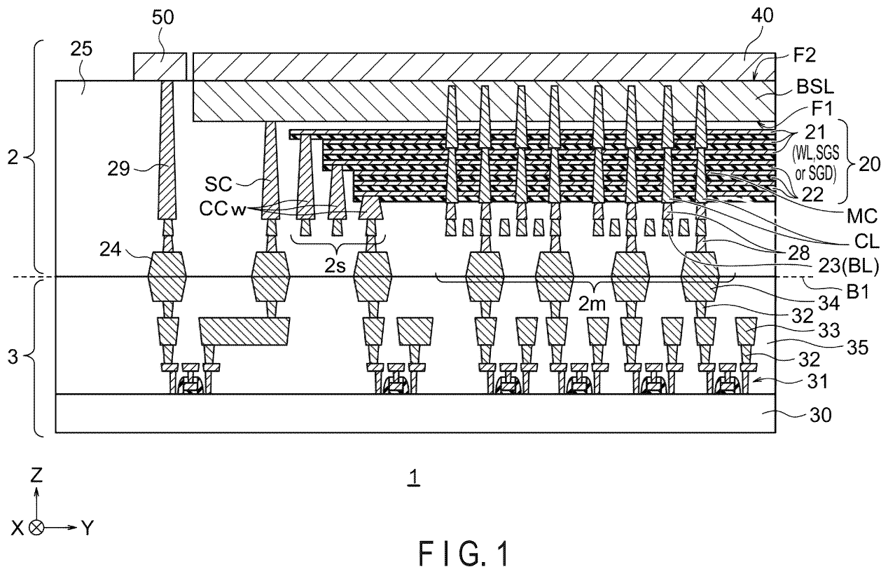

FIG. 1 is a cross-sectional view illustrating a configuration example of a semiconductor memory device 1 according to a first embodiment. Hereinafter, a stacking direction of a stacked body 20 is defined as a Z direction. A direction perpendicular to the Z direction is defined as a Y direction. Another direction perpendicular to the Z direction and the Y direction is defined as an X direction.

The semiconductor memory device 1 includes an array chip 2 including a memory cell array and includes a CMOS chip 3 including a CMOS circuit. The array chip 2 and the CMOS chip 3 are bonded together at a bonding surface B1 and electrically connected to each other via wires that are joined at the bonding surface B1. FIG. 1 illustrates a state where the array chip 2 is mounted on the CMOS chip 3.

The CMOS chip 3 includes a substrate 30, transistors 31, vias 32, wires 33 and 34, and an interlayer dielectric layer 35.

The substrate 30 is, for example, a semiconductor substrate such as a silicon substrate. The transistors 31 are NMOS or PMOS transistors provided on the substrate 30. The transistors 31 constitute, for example, a CMOS circuit that controls the memory cell array of the array chip 2. The transistors 31 form logic circuits such as sense amplifiers, row decoders, and column decoders. On the substrate 30, semiconductor elements other than the transistors 31, such as resistive elements and capacitive elements may be formed.

The vias 32 electrically connect the transistors 31 and the wires 33 and connect the wires 33 and the wires 34. The wires 33 and 34 constitute a multilayered interconnection structure in the interlayer dielectric layer 35. The wires 34 are in the interlayer dielectric layer 35 and are exposed at a surface of the interlayer dielectric layer 35 and are substantially flush with this surface. The wires 33 and 34 are electrically connected to the transistors 31 and the like. As the vias 32, and the wires 33 and 34, for example, a low-resistance metal such as copper or tungsten is used. The transistors 31, the vias 32, and the wires 33 and 34 are covered with and protected by the interlayer dielectric layer 35. As the interlayer dielectric layer 35, for example, an insulation layer such as a silicon oxide film is used.

The array chip 2 includes the stacked body 20, columnar bodies CL, slits ST (LI), a source layer BSL, a metal layer 40, contacts CCw, a contact plug 29, and a bonding pad 50.

The stacked body 20 is provided above the transistors 31 and is located in the Z direction with respect to the substrate 30. The stacked body 20 is formed by stacking a plurality of conductive films 21 and a plurality of insulation films 22 alternately along the Z direction. The stacked body 20 forms the memory cell array. As the conductive films 21, for example, a conductive metal such as tungsten is used. As the insulation films 22, for example, an insulation layer such as a silicon oxide film is used. The insulation films 22 insulate the conductive films 21 from each other. That is, the conductive films 21 are stacked being insulated from each other. The numbers of stack layers of the conductive films 21 and the insulation films 22 are any numbers. The insulation films 22 may be each, for example, a porous insulation layer or an air gap.

One or more of the conductive films 21 at an upper end of the stacked body 20 in the Z direction function as source-side selector gates SGS, and one or more of the conductive films 21 at a lower end of the stacked body 20 in the Z direction function as drain-side selector gates SGD. Conductive films 21 between the source-side selector gates SGS and the drain-side selector gates SGD function as word lines WL. The word lines WL are gate electrodes of memory cells MC. The drain-side selector gates SGD are gate electrodes of drain-side selection transistors. The source-side selector gates SGS are provided in an upper region of the stacked body 20. The drain-side selector gates SGD are provided in a lower region of the stacked body 20. The upper region refers to a region of the stacked body 20 closer to the CMOS chip 3, and the lower region refers to a region of the stacked body 20 farther from the CMOS chip 3 (closer to the metal layer 40).

The semiconductor memory device 1 includes the memory cells MC that are connected in series between source-side selection transistors and the drain-side selection transistors. Structures in which the source-side selection transistors, the memory cells MC, and the drain-side selection transistors are connected in series are called “memory strings” or “NAND strings.” The memory strings are connected to bit lines BL via, for example, vias 28. The bit lines BL are wires 23 that are provided below the stacked body 20 (on the upper region side) and extend in the X direction.

In the stacked body 20, the columnar bodies CL are provided. The columnar bodies CL extend in the stacked body 20 in such a manner as to penetrate the stacked body 20 in the stacking direction of the stacked body (the Z direction) and are provided from the vias 28 connected to the bit lines BL to the source layer BSL. An internal structure of the columnar bodies CL will be described later. Note that, in the present embodiment, the columnar bodies CL have a high aspect ratio. Thus, the columnar bodies CL are each formed in two segments in the Z direction. However, the columnar bodies CL each having one segment or three or more segments cause no problem.

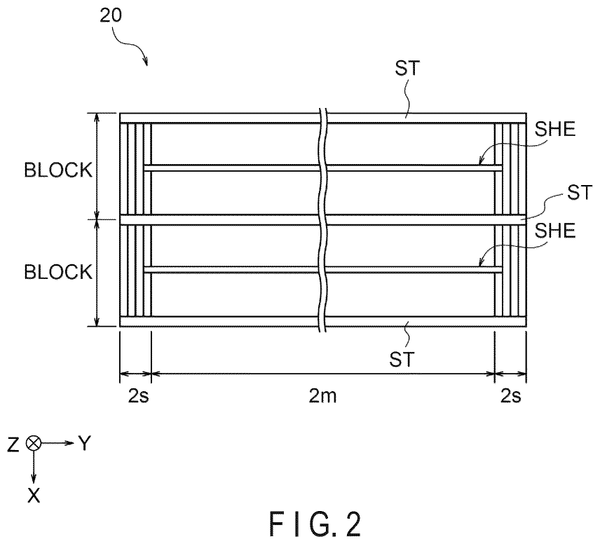

Although not illustrated in FIG. 1, the slits ST (see FIG. 2) are provided in the stacked body 20. The slits ST extend in the Y direction and penetrate the stacked body 20 in the stacking direction of the stacked body 20 (the Z direction). The slits ST are filled with an insulation material such as a silicon oxide film and the insulation material is formed in a plate shape. The slits ST electrically isolate the conductive films 21 of the stacked body 20. Alternatively, inner walls of the slits ST may be covered with insulation layers such as a silicon oxide film and a conductive material may be embedded inside these insulation layers. In this case, the conductive material also functions as source lines that reach the source layer BSL.

Above (on the lower region side of) the stacked body 20, the source layer BSL is provided. The source layer BSL is an example of a first semiconductor layer. The source layer BSL is provided corresponding to the stacked body 20. The source layer BSL includes a first surface F1 and a second surface F2 that is on an opposite side to the first surface F1. On the first surface F1 side of the source layer BSL, the stacked body 20 (the memory cell array) is provided, and on the second surface F2 side, the metal layer 40 is provided. The source layer BSL is connected in common to ends of the columnar bodies CL and provides a common source potential to a plurality of columnar bodies CL in the same memory cell array 2m. That is, the source layer BSL functions as a common source electrode of the memory cell array 2m. As the source layer BSL, for example, a conductive material such as a doped silicon is used. As the metal layer 40, for example, a metallic material having a resistance lower than the source layer BSL, such as copper, aluminum, or tungsten, is used. Staircase portions 2s of the conductive films 21 that are provided so the conductive films 21 can be connected to contacts. The staircase portions 2s will be described with reference to FIG. 2.

In a region above the stacked body 20 where the source layer BSL is not provided, the bonding pad 50 is provided. The bonding pad 50 is connected to a metallic wire or the like and receives power or signals from an outside of the semiconductor memory device 1. The bonding pad 50 is provided in such a manner as to be connected to one end of the contact plug 29 in the Z direction. The bonding pad 50 is connected to the transistors 31 of the CMOS chip 3 via the contact plug 29, wires 24, and the wires 34. Therefore, external power supplied through the bonding pad 50 is supplied to the transistors 31. Alternatively, signals are supplied to the transistors 31 or the memory cell array 2m via the bonding pad 50.

The contacts CCw are provided in a periphery of the stacked body 20 and extend in an interlayer dielectric layer 25 in the Z direction. The contacts CCw are electrically connected between the conductive films 21 (the word lines WL) and the wires 24. The contacts CCw are provided at the staircase portions 2s, which are formed at edge portions of the stacked body 20 in a staircase pattern, and are electrically connected to the conductive films 21. The contacts CCw are provided to transfer a word line voltage from the CMOS chip 3 to the conductive films 21. As the contacts CCw, for example, a low-resistance metal such as copper or tungsten is used.

The contact plug 29 is provided in a periphery of the stacked body 20 and extends in an interlayer dielectric layer 25 in the Z direction. The contact plug 29 is a contact plug that is provided from a wire 24 to the bonding pad 50.

The contact plug 29 is electrically connected between the bonding pad 50 and the wire 24. The contact plug 29 is used to supply a power voltage or signals from the bonding pad 50 to the array chip 2 or the CMOS chip 3. As the contact plug 29, for example, a low-resistance metal such as copper or tungsten is used. The power voltage may be a power voltage VDD that is a high-level voltage or a reference voltage VSS that is a low-level voltage (e.g., a ground voltage). The signals may be control signals from the outside or may be data to be written or read data.

In the present embodiment, the array chip 2 and the CMOS chip 3 are formed individually and bonded together at the bonding surface B1. Therefore, in the array chip 2, the transistors 31 are not provided. In the CMOS chip 3, the stacked body 20 (the memory cell array) is not provided. The transistors 31 and the stacked body 20 are both present on the first surface F1 side of the source layer BSL. The transistors 31 are present on an opposite side of the source layer BSL to the second surface F2, on which the metal layer 40 is present.

Below (on the upper region side of) the stacked body 20, the vias 28, the wires 23, and the wires 24 are provided. The wires 23 and 24 are in the interlayer dielectric layer 25. The wires 24 are exposed at a surface of the interlayer dielectric layer 25 and are substantially flush with this surface. The wires 23 and 24 are electrically connected to semiconductor bodies 210 and the like of the columnar bodies CL. As the vias 28, the wires 23, and the wires 24, a low-resistance metal such as copper or tungsten can be used. The stacked body 20, the vias 28, the wires 23, and the wires 24 are covered with and protected by the interlayer dielectric layer 25. As the interlayer dielectric layer 25, for example, an insulation layer such as a silicon oxide film is used.

The interlayer dielectric layer 25 and the interlayer dielectric layer 35 are bonded together at the bonding surface B1, and the wires 24 and the wires 34 are joined together at the bonding surface B1, being substantially flush with each other. This causes the array chip 2 and the CMOS chip 3 to be electrically connected together via the wires 24 and wires 34.

FIG. 2 is a schematic plan view illustrating the stacked body 20. The stacked body 20 includes the staircase portions 2s and the memory cell array 2m. The staircase portions 2s are provided at the edge portions of the stacked body 20. The memory cell array 2m is sandwiched between or surrounded by the staircase portions 2s. The slits ST (LI) are provided from a staircase portion 2s at one edge of the stacked body 20 via the memory cell array 2m to a staircase portion 2s at another edge of the stacked body 20. Slits SHE are provided at least in the memory cell array 2m. The slits SHE are shallower than the slits ST (LI) and extend substantially parallel to the slits ST (LI). The slits SHE are provided to electrically isolate the conductive films 21 for each of the drain-side selector gates SGD. Alternatively, the slits ST may be source lines LI that are electrically connected to the source layer BSL while being electrically isolated from the conductive films 21 of the stacked body 20. That is, the slits ST may be source lines LI that are electrically isolated from the conductive films 21 of the stacked body 20 constituting the memory cell array and electrically connected to the source layer BSL.

A portion of the stacked body 20 sandwiched between every two adjacent slits ST illustrated in FIG. 2 is called a block (BLOCK). The block forms, for example, a minimum unit for data erasure operations. Each of the slits SHE is provided inside a block. A portion of the stacked body 20 between a slit ST and a slit SHE can be called a finger. The drain-side selector gates SGD are partitioned among fingers. Therefore, when data is written or read, one drain-side selector gate SGD can bring one finger in a block into a selected state.

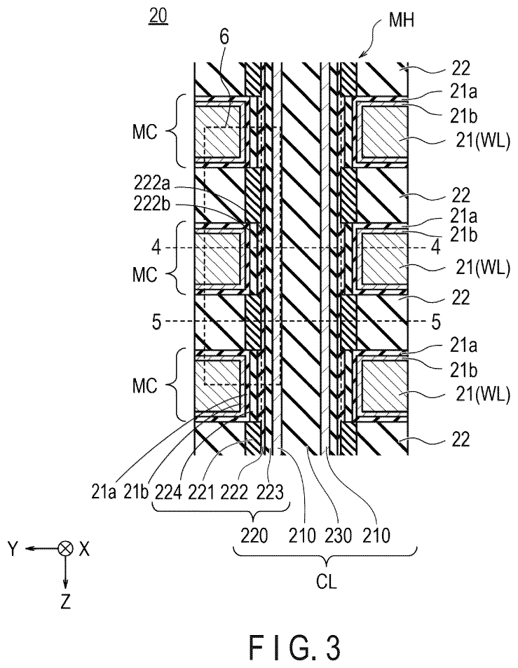

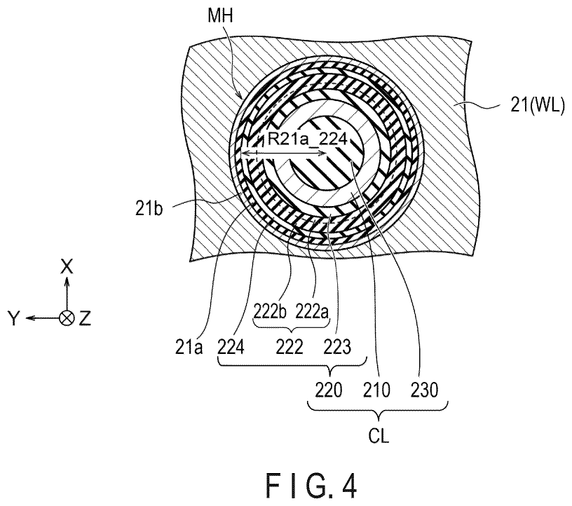

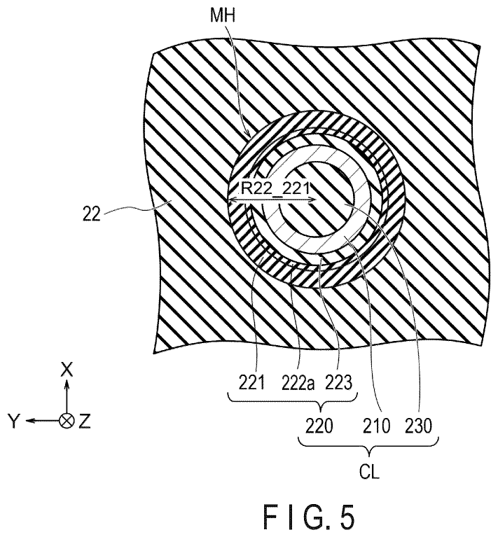

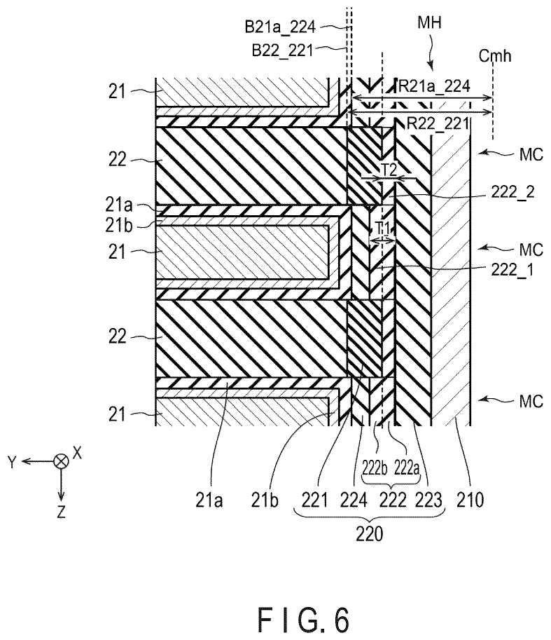

FIG. 3 is a schematic cross-sectional view depicting the memory cell array. FIG. 4 illustrates a section taken along the line 4-4 in FIG. 3, and FIG. 5 illustrates a section taken along the line 5-5 in FIG. 3. FIG. 6 illustrates an enlarged cross-section of the portion surrounded by the dashed box 6 in FIG. 3.

As illustrated in FIG. 3, each of the columnar bodies CL is in a memory hole MH provided in the stacked body 20. Each columnar body CL penetrates the stacked body 20 from the upper end of the stacked body 20 along the Z direction and is provided in the stacked body 20 and the source layer BSL. The columnar bodies CL each include a semiconductor body 210, a memory film 220, and a core layer 230. Each columnar body CL includes the core layer 230 provided at a center portion of the columnar body CL, the semiconductor body (semiconductor layer) 210 provided surrounding the core layer 230, and the memory film 220 provided surrounding the semiconductor body 210. The semiconductor body 210 extends in the stacking direction (the Z direction) within the stacked body 20. The semiconductor body 210 is electrically connected to the source layer BSL. The memory film 220 is provided between the semiconductor body 210 and the conductive films 21 and includes therein a charge trapping film. A plurality of columnar bodies CL that can be selected individually from the respective fingers are connected to one shared bit line BL via the vias 28 in FIG. 1. The columnar bodies CL are provided in, for example, a region of the memory cell array 2m.

As illustrated in FIG. 3 and FIG. 6, between the conductive films 21 and the insulation films 22 and between the conductive films 21 and block insulation layers 224, block insulation layers 21a and barrier films 21b, which constitute part of the memory film 220, are provided. The block insulation layers 21a (as third insulation parts) are provided between the conductive films 21 and the insulation films 22 and also between the conductive films 21 and the block insulation layers 224 or a charge trapping film 222. The block insulation layers 21a are made of, for example, silicon oxide or a metallic oxide. An example of the metallic oxide is an aluminum oxide. The block insulation layers 21a inhibit back tunneling of electric charge from the conductive films 21 toward the memory film 220. As the barrier films 21b a layered film of titanium nitride and titanium can be used in a case where the conductive films 21 are made of tungsten. The barrier films 21b are made of a conductive material that serves to improve adhesion between the conductive films 21 and the block insulation layers 21a. As the barrier films 21b, for example, a conductive metal compound such as a layered film of titanium nitride and titanium is used.

As illustrated in FIG. 4 and FIG. 5, the memory hole MH in an X-Y plane cross-section has, for example, a circular or elliptic shape. The core layer 230 is present at a center of the memory hole MH. The semiconductor body 210 and the memory film 220 are provided surrounding the core layer 230.

The semiconductor body 210 has, for example, a cylindrical shape. As the semiconductor body 210, for example, polysilicon is used. The semiconductor body 210 is, for example, undoped silicon. Alternatively, the semiconductor body 210 may be made of p-type silicon. The semiconductor body 210 serves as a channel of each of a drain-side selection transistor STD, memory cells MC, and source-side selection transistor STS. One end of each of the semiconductor bodies 210 in the same memory cell array 2m is electrically connected to the source layer BSL in common.

The memory film 220 is provided between an inner wall of the memory hole MH and the semiconductor body 210. The memory film 220 has, for example, a cylindrical shape. The memory cells MC each include a storage region between a semiconductor body 210 and conductive films 21 serving as word lines WL and are stacked in the Z direction. The memory film 220 includes, for example, block insulation layers 224 in FIG. 4, cover insulation layers 221 in FIG. 5, the charge trapping film 222 (222a, 222b), and a tunnel insulation layer 223. The semiconductor body 210, the charge trapping film 222, and the tunnel insulation layer 223 each extend in the Z direction.

As illustrated in FIG. 6, the cover insulation layers 221 as fourth insulation parts are provided between part of the charge trapping film 222 (222a) (as a second insulation part) and the insulation films 22. The cover insulation layers 221 are provided intermittently in the Z direction. The cover insulation layers 221 that are adjacent in the Z direction are isolated from one another by the block insulation layers 224 and parts of the charge trapping film 222 (222b).

In the memory hole MH, the cover insulation layers 221 and the block insulation layers 224 are provided around the charge trapping film 222. As the cover insulation layers 221, insulation layers that are films different from the charge trapping films can be made of such materials as silicon oxide, HfO, or Zro.

The cover insulation layers 221 are provided between the block insulation layers 224 that are adjacent in the Z direction and between second charge trapping films 222b that are adjacent in the Z direction. The cover insulation layers 221 have a thickness in the X direction or the Y direction greater than the block insulation layers 224.

The block insulation layers 224 are provided between the conductive films 21 and the charge trapping film 222. As the block insulation layers 224, an insulation layer made of, for example, silicon oxide is used. The block insulation layers 224 inhibit, together with block insulation layers 21a, back tunneling of electric charge from the conductive film 21 toward the memory film 220.

The charge trapping film 222 as the second insulation part is provided between the stacked body 20 and the tunnel insulation layer 223. The charge trapping film 222 is provided between the cover insulation layers 221 and the tunnel insulation layer 223 and between the block insulation layers 224 and the tunnel insulation layer 223. The charge trapping film 222 includes a first charge trapping film 222a and the second charge trapping films 222b. The first charge trapping film 222a is provided between the second charge trapping films 222b or the cover insulation layers 221 and the tunnel insulation layer 223 and continuously extend in the Z direction. The second charge trapping films 222b are provided between the conductive films 21 or the block insulation layers 224 and the first charge trapping film 222a and are provided intermittently in the Z direction. As the first and second charge trapping films 222a and 222b, an insulation layer made of, for example, a silicon nitride is used.

The first and second charge trapping films 222a and 222b each include a trap site that traps electric charge in the films. That is, the first and second charge trapping films 222a and 222b are configured as one charge trapping film 222. In the charge trapping film 222, first portions 222_1 sandwiched between the conductive films 21 serving as the word lines WL (including barrier films 21b) and the semiconductor body 210 and/or between the block insulation layers 21a and the semiconductor body 210 comprises the first and second charge trapping films 222a and 222b. A first portion 222_1 corresponding to each memory cell MC accumulates electric charge, thus functioning as a storage region of the memory cell MC. In the charge trapping film 222, second portions 222_2 provided between the insulation films 22 (the cover insulation layers 221) and the tunnel insulation layer 223 comprise the first charge trapping film 222a. The second portions 222_2 are provided between the first portions 222_1 adjacent in the Z direction. A thickness T2 of the second portions 222_2 of the charge trapping film 222 in the Y direction or the X direction is smaller than a thickness T1 of the first portions 222_1 in the Y direction or the X direction by a thickness of the second charge trapping films 222b. This isolates the first portions 222_1 of a plurality of memory cells MC adjacent in the Z direction and can inhibit electric charge accumulated in the charge trapping film from moving in the first portions 222_1 adjacent in the Z direction. This can inhibit interference between the memory cells MC adjacent in the Z direction. In addition, by making the first portions 222_1 have a capacitance greater than a capacitance of the second portions 222_2, it is possible for each memory cell MC to accumulate more electric charge. A threshold voltage of the memory cells MC varies in accordance with presence or absence of electric charge in the first portions 222_1 of the charge trapping film 222 or an amount of electric charge (charge level) trapped in the first portions 222_1. This enables the memory cells MC to retain information (data).

The tunnel insulation layer 223 (as a first insulation part) is provided between the stacked body 20 and the semiconductor body 210. Specifically, the tunnel insulation layer 223 provided between the semiconductor body 210 and the charge trapping film 222. As the tunnel insulation layer 223, an insulation layer made of, for example, silicon oxide or a silicon oxynitride film is used. The tunnel insulation layer 223 serves as a potential barrier between the semiconductor body 210 and the charge trapping film 222. For example, when electrons are injected from the semiconductor body 210 into the charge trapping film 222 (e.g., in a writing operation) or when positive holes are injected from the semiconductor body 210 into the charge trapping film 222 (e.g., in an erasing operation), the electrons or the positive holes pass the potential barrier of the tunnel insulation layer 223 (tunneling).

The core layer 230 fills an inner space formed by the cylindrical semiconductor body 210. The core layer 230 has, for example, a columnar shape. As the core layer 230, for example, an insulation material such as silicon oxide is used.

The block insulation layers 21a as fifth insulation parts are provided between the block insulation layers 224 and the barrier films 21b or the conductive films 21. The block insulation layers 21a are also provided between the insulation films 22 and the barrier film 21b or the conductive films 21. The block insulation layers 21a are formed of an insulation material having a relative permittivity higher than a relative permittivity of the block insulation layers 224 (a High-k material). As the block insulation layers 21a, for example, an aluminum oxide film (Al₂O₃), which has a relative permittivity higher than a relative permittivity of a silicon oxide film, is used.

The barrier 21b films are provided between the conductive films 21 and the block insulation layers 21a. As described above, as the barrier films 21b, a layered film of titanium nitride and titanium is selected in a case where, for example, the conductive films 21 are made of tungsten. The barrier films 21b are very thin compared with the conductive films 21 and may be considered as functioning as parts of the conductive films 21. Accordingly, the conductive films 21 may include the barrier films 21b.

As illustrated in FIG. 6, when a boundary between a block insulation layer 21a and a block insulation layer 224 is denoted by B21a_224, and a boundary between an insulation film 22 and a cover insulation layer 221 is denoted by B22_221, the boundary B21a_224 is at the same position as or a position inner than the boundary B22_221 in the memory hole MH (closer to the center of the memory hole MH) in an X-Y plane. That is, a radius R21a_224 of the memory hole MH or the columnar body CL at the boundary B21a_224 (see FIG. 4) is equal to or smaller than a radius R22_221 of the memory hole MH or the columnar body CL at the boundary B22_221 (see FIG. 5) in an X-Y plane. In a case where the boundary B21a_224 and the boundary B22_221 are at the same position, the boundary B21a_224 and the boundary B22_221 coincide with each other in an X-Y plane.

According to the present embodiment, the boundary B21a_224 coincides with the boundary B22_221 or is closer to a center Cmh of the memory hole MH than the boundary B22_221 in an X-Y plane. This causes the conductive films 21 to protrude toward the memory hole MH and the columnar body CL, and thus it is possible to satisfactorily control electric charge accumulated in the first portions 222_1 of the charge trapping film 222. In addition, by virtue of the conductive films 21 protruding toward the center Cmh of the memory hole MH from a side surface of the memory hole MH as being originally formed (the boundary B22_221), embedding properties of a metallic material of the conductive films 21 does not deteriorate even when a distance between adjacent memory holes MH in the same WL plane is decreased. Therefore, even when the intervals between memory holes MH adjacent to each other in an X-Y plane are reduced, the material of the conductive films 21 can be embedded (filled) into spaces between the insulation films 22, and thus the reduction of the intervals has no adverse effect on the replacement step. As a result, a cell size of the memory cell array 2m can be reduced.

### Second Embodiment

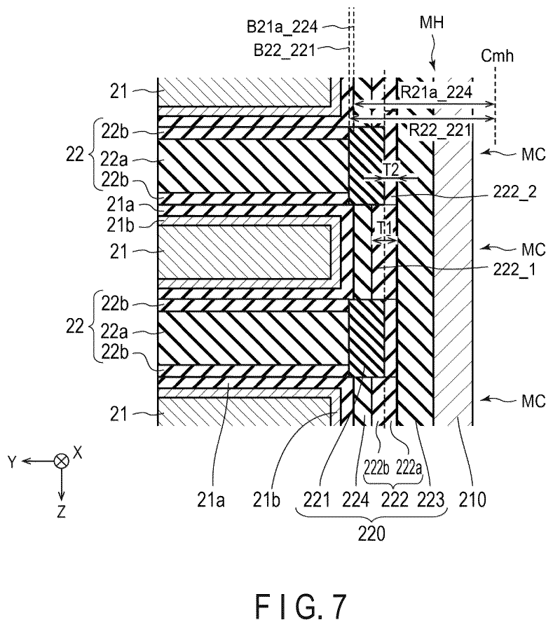

FIG. 7 is a schematic cross-sectional view depicting a memory cell array according to a second embodiment. In the seventh embodiment, insulation films 22 are a layered film comprising insulation films 22a and 22b. The insulation film 22a (as a second insulating film) is provided in a center portion of each insulation film 22 and formed of, for example, a silicon oxide film. The insulation films 22b are provided on both sides of the insulation film 22a in such a manner as to sandwich the insulation film 22a in the Z direction. For example, as the insulation films 22b, an insulation material such as SiOC can be used. In a case where SiOC is used as the insulation films 22b, an element ratio of carbon can be adjusted such that an etching rate of the insulation films 22b in hydrofluoric acid becomes lower than that of the silicon oxide film. The density of carbon in SiOC is, for example, 5×10²⁰ to 1×10²² atom/cm³.

In a cross-section taken along the Z direction illustrated in FIG. 7, the insulation film 22a is sandwiched between the insulation films 22b from above and below in the Z direction. The insulation films 22b are provided between the insulation film 22a and block insulation layers 21a.

The rest of the configuration of the second embodiment may be the same as in the first embodiment. Therefore, the second embodiment can provide the same effects as the first embodiment. A method for producing according to the second embodiment will be described later.

### Third Embodiment

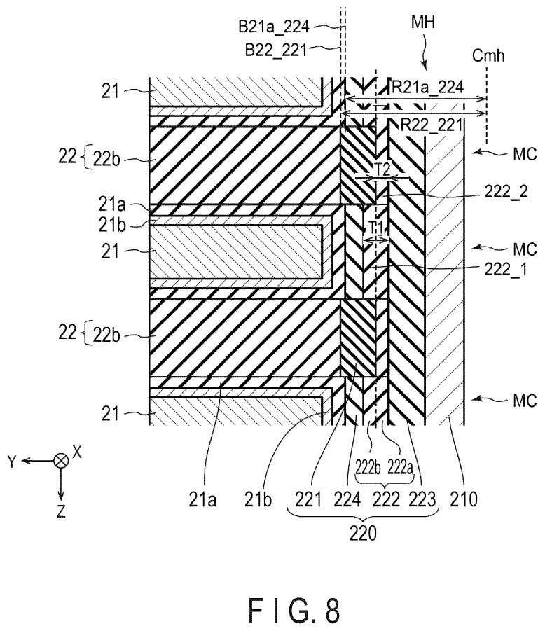

FIG. 8 is a schematic cross-sectional view depicting a memory cell array according to a third embodiment. In the third embodiment, each of insulation films 22 is entirely made of the material of the insulation films 22b. For example, as the insulation films 22, an insulation material such as SiOC (silicon oxycarbide) that is a silicon oxide film including carbon is used.

The rest of the configuration of the third embodiment may be the same as in the first embodiment. Therefore, the third embodiment can provide the same effects as the first embodiment. A method for producing according to the third embodiment will be described later.

### Fourth Embodiment

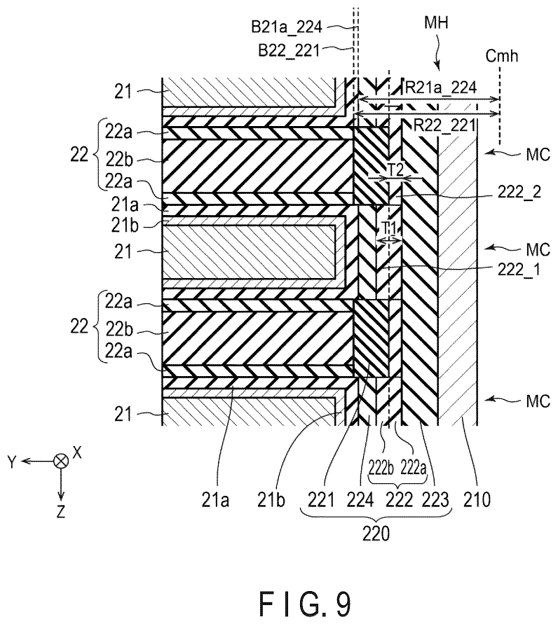

FIG. 9 is a schematic cross-sectional view depicting a memory cell array according to a fourth embodiment. In the fourth embodiment, each of the insulation films 22b is provided at a center portion of an insulation film 22. Insulation films 22a are provided on both sides of the insulation film 22b in such a manner as to sandwich the insulation film 22b in the Z direction. The insulation films 22a are provided around the insulation film 22b. Materials of the insulation films 22a and 22b may be the same as the materials of those in the second embodiment.

In a cross-section parallel to the Z direction illustrated in FIG. 9, each of the insulation films 22b is sandwiched between insulation films 22a from above and below in the Z direction. The insulation films 22a are provided between the insulation film 22b and block insulation layers 21a.

In this manner, in the insulation film 22, the insulation film 22b may be sandwiched between the insulation films 22a from above and below in the Z direction.

The rest of the configuration of the fourth embodiment may be the same as in the first embodiment. Therefore, the fourth embodiment can provide the same effects as the first embodiment. A method for producing according to the fourth embodiment will be described later.

### Fifth Embodiment

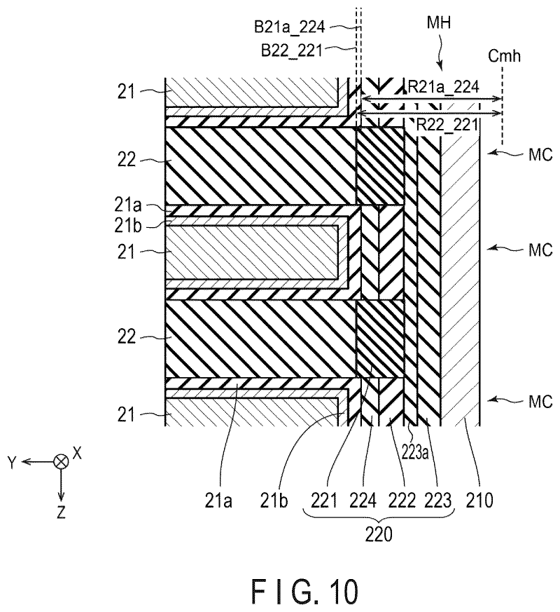

FIG. 10 is a schematic cross-sectional view depicting a memory cell array according to a fifth embodiment. In a fifth embodiment, no first charge trapping film 222a is provided. Accordingly, each of charge trapping films 222 is provided between a conductive film 21 or a block insulation layer 21a and a tunnel insulation layer 223 but is not provided between an insulation film 22 or a cover insulation layer 221 and the tunnel insulation layer 223. This causes cover insulation layers 221 to completely isolate the charge trapping films 222 from one another in the Z direction for each memory cell MC. This makes it possible to further reliably inhibit electric charge from moving in the charge trapping films 222 of a plurality of memory cells MC adjacent in the Z direction.

Instead of the first charge trapping film 222a, a seed insulation film 223a is provided between the charge trapping films 222 and the tunnel insulation layer 223. The seed insulation film 223a may be part of the tunnel insulation layer 223 and is formed of, for example, a high-dielectric material such as an aluminum oxide film.

The rest of the configuration of the fifth embodiment may be the same as in the first embodiment. Therefore, the fifth embodiment can provide the same effects as the first embodiment. In addition, the fifth embodiment may be combined with any one of the second to fourth embodiments. This enables the fifth embodiment to provide the effects of any one of the second to fourth embodiments.

### Sixth Embodiment

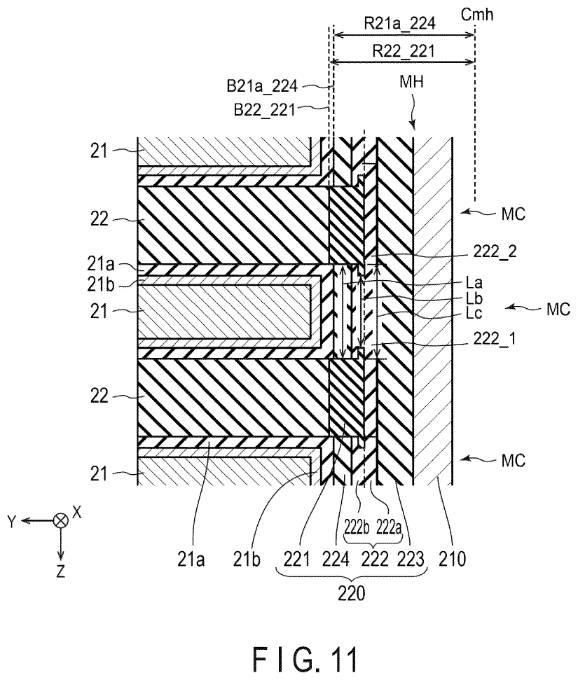

FIG. 11 is a schematic cross-sectional view depicting a memory cell array according to a sixth embodiment. In the sixth embodiment, in its cross-section along the Z direction, cover insulation layers 221 each have a T shape facing upward in a-Y direction. Accordingly, second charge trapping films 222b each have a T shape facing upward in a +Y direction. Accordingly, in the cross-section taken along (parallel to) the Z direction, a length La of a boundary between a first portion 222_1 of a charge trapping film 222 and a block insulation layer 224 is longer than a length Lb of the first portion 222_1 on an extended line at a boundary between a second portion 222_2 of the charge trapping film 222 and a cover insulation layer 221. That is, the length Lb corresponds a shortest distance between adjacent cover insulation layers 221 along the Z-direction. In addition, a length Lc of a boundary between the first portions 222_1 and a tunnel insulation layer 223 is longer than the length Lb. In the Z direction, one end of the length Lc is located at a boundary between an insulation film 22 and a block insulation layer 21a, and the other end is located at a boundary between an insulation film 22 and a block insulation layer 21a adjacent to the insulation film 22 and the block insulation layer 21a at the one end. In this manner, side surfaces of the first portions 222_1 in the Z direction include recessed portions, and portions of cover insulation layers 221 enter into the recessed portions.

This partially widens the distance between adjacent CTs, thus reducing a parasitic capacitance that occurs between adjacent charge accumulation layers 222b.

The rest of the configuration of the sixth embodiment may be the same as in the first embodiment. Therefore, the sixth embodiment can provide the same effects as the first embodiment. In addition, the sixth embodiment may be combined with any one of the second to fifth embodiments. This enables the sixth embodiment to provide the effects of any one of the second to fifth embodiments.

### Seventh Embodiment

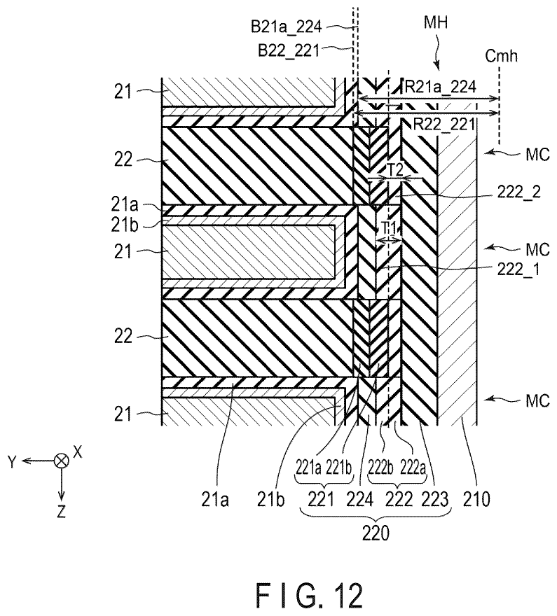

FIG. 12 is a schematic cross-sectional view depicting a memory cell array according to a seventh embodiment. In the seventh embodiment, cover insulation layers 221 are each a layered film comprising insulation layers 221a and 221b. Materials of the insulation layers 221a and 221b may be different from each other. For example, the insulation layer 221a may be a silicon oxide film, a hafnium oxide film, or a zirconium oxide film. The insulation layer 221b may be an aluminum oxide film or a hafnium oxide film.

The rest of the configuration of the seventh embodiment may be the same as in the first embodiment. Therefore, the seventh embodiment can provide the same effects as the first embodiment. In addition, the seventh embodiment may be combined with any one of the second to sixth embodiments. This enables the seventh embodiment to provide the effects of any one of the second to sixth embodiments.

### Eighth Embodiment

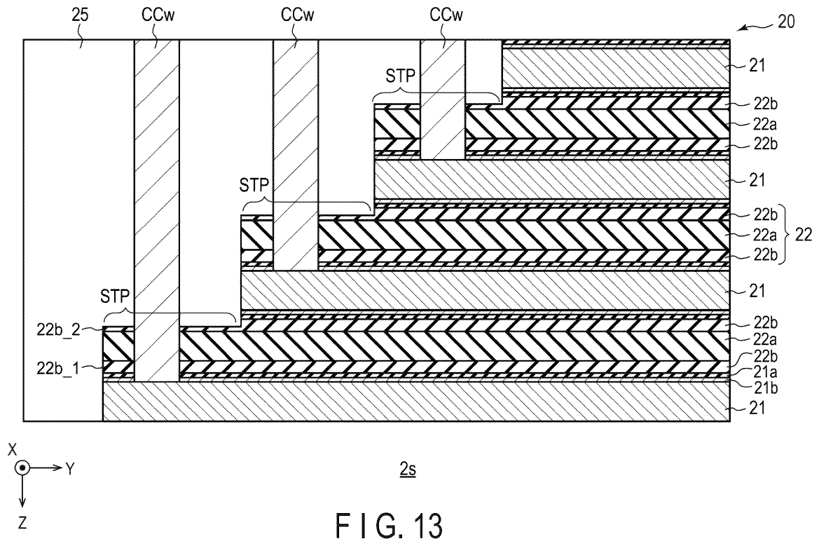

FIG. 13 is a schematic cross-sectional view depicting a staircase portion 2s of a memory cell array according to an eighth embodiment. The staircase portion 2s in the eighth embodiment corresponds to a staircase portion 2s of the memory cell array of the second embodiment. In the staircase portion 2s, conductive films 21 and insulation films 22 are formed in a staircase pattern. The conductive films 21 are covered with the respective insulation films 22 at step faces (contact regions of contacts CCw) STP in the staircase portion 2s. An insulation film 22a of each insulation film 22 is provided at a center portion of the insulation film 22 in the Z direction. Insulation films 22b are provided on both sides of the insulation film 22a in such a manner as to sandwich the insulation film 22a in the Z direction. Materials of the insulation films 22a and 22b may be the same as those in FIG. 7.

In the staircase portion 2s, the contacts CCw penetrate the insulation films 22 in the contact regions exposed from the stacked body 20 and are connected to the conductive films 21 under the respective insulation films 22.

The insulation films 22b include insulation films 22b_1 and 22b_2 that sandwich the insulation film 22a from both sides in the Z direction. The insulation film 22b_1 is provided between a conductive film 21 and the insulation film 22a. The insulation film 22b_2 is on the insulation film 22a and is provided between the insulation film 22a and an interlayer dielectric layer 25. The insulation film 22b_2 is thinner than the insulation film 22b_1 because the insulation film 22b_2 is to be etched when the staircase portion 2s is formed. That is, the insulation film 22b_1 is thicker than the insulation film 22b_2.

Next, methods for producing according to the above embodiments will be described.

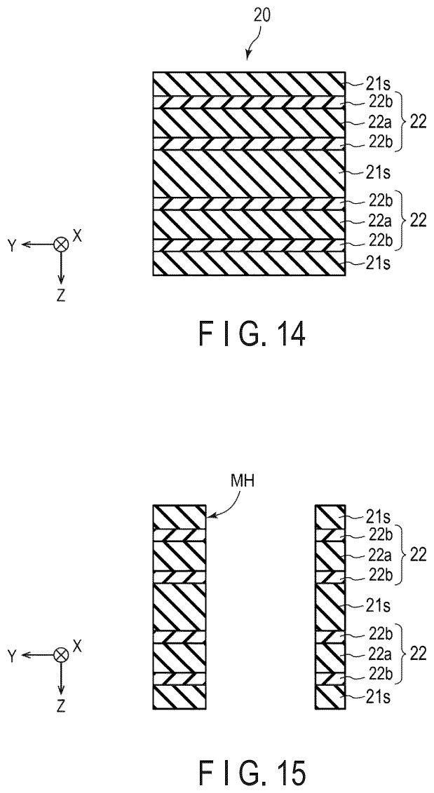

FIG. 14 to FIG. 20 are cross-sectional views illustrating an example of a method for producing the semiconductor memory device according to the first embodiment.

First, as illustrated in FIG. 14, sacrificial films 21s and insulation films 22 are stacked alternately in the Z direction on a semiconductor substrate 10 by using, for example, a chemical vapor deposition (CVD) method. This forms a stacked body 20 in which the sacrificial films 21s and the insulation films 22 are stacked in the Z direction. The sacrificial films 21s are insulating films such as a silicon nitride film. The sacrificial films 21s are replaced with a material of conductive films 21 in a later step. The insulation films 22 are to be interlayer dielectric layers between the conductive films 21. The insulation films 22 are each a layered film in which an insulation film 22a is sandwiched between two insulation films 22b. The insulation film 22a is, for example, a silicon oxide film. The insulation films 22b are formed of, for example, a silicon oxycarbide (SiOC) film. When the sacrificial films 21s and the insulation films 22 are stacked alternately, films 21s and the insulation films 22a and 22b are deposited in order of 22b, 22a, 22b, 21s, 22b, 22a, 22b, 21s, and so forth.

Next, as illustrated in FIG. 15, memory holes MH that extend in the Z direction in the stacked body 20 are formed by using, for example, a lithography technology and a reactive ion etching (RIE) method. These memory holes MH penetrate the stacked body 20 constituted by the insulation films 22 and the sacrificial films 21s.

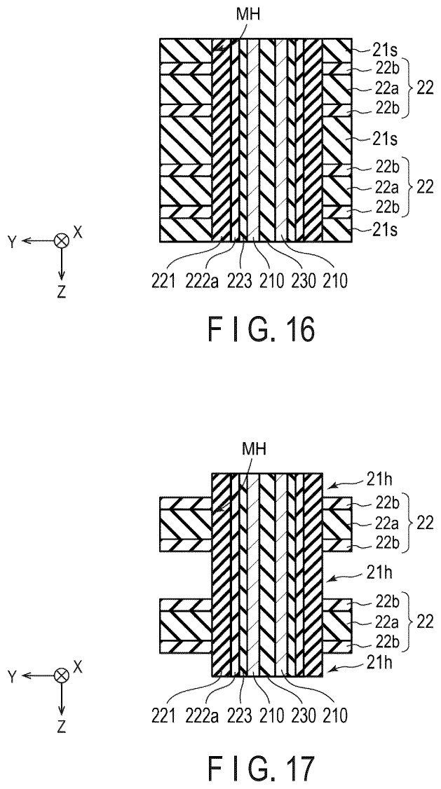

Next, as illustrated in FIG. 16, a cover insulation layer 221, a charge trapping film 222a, a tunnel insulation layer 223, and a semiconductor body 210 are deposited on an inner wall of each of the memory holes MH by using an atomic layer deposition (ALD) method or a CVD method. Inside the semiconductor body 210 in each memory hole MH, a core layer 230 is formed. The charge trapping film 222a is, for example, an insulating film such as a silicon nitride film. The charge trapping film 222a functions as a seed (seed layer) for a charge trapping film 222b, which is selectively grown later. The cover insulation layer 221 and the tunnel insulation layer 223 are insulation layers such as a silicon oxide film. The tunnel insulation layer 223 may be a silicon oxynitride layer. The semiconductor body 210 is a semiconductor layer that comprises a semiconductor material such as polysilicon.

Next, the method proceeds to a step of replacing the sacrificial films 21s. As illustrated in FIG. 17, the sacrificial films 21s are selectively etched to be removed using a solution or gas that contains phosphoric acid or the like. The removal of the sacrificial films 21s is executed via slits ST (see FIG. 2) formed in the stacked body 20. This exposes the cover insulation layer 221 in spaces 21h after the sacrificial films 21s are removed.

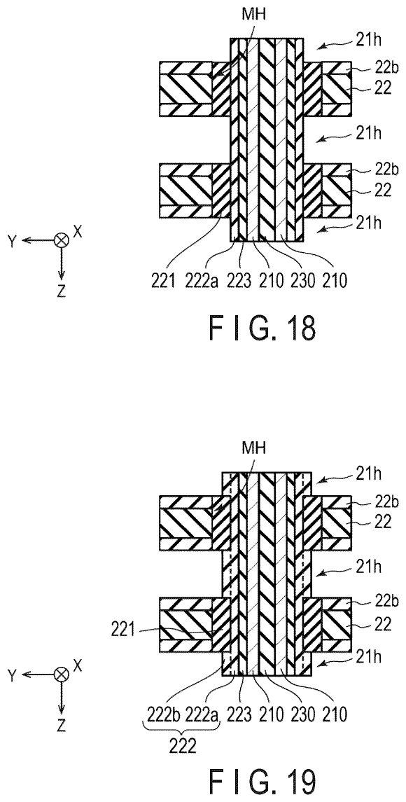

Next, as illustrated in FIG. 18, the cover insulation layer 221 is isotropically etched using a solution or gas that comprises hydrofluoric acid or the like. This exposes the charge trapping film 222a in the spaces 21h.

Next, as illustrated in FIG. 19, with the charge trapping film 222a exposed in the spaces 21h being used as a seed, a charge trapping film 222b is grown on the charge trapping film 222a. In the spaces 21h, which are regions for ultimately forming the conductive films 21, this makes the charge trapping film 222 thicker than the charge trapping film 222a between the cover insulation layer 221 and the tunnel insulation layer 223.

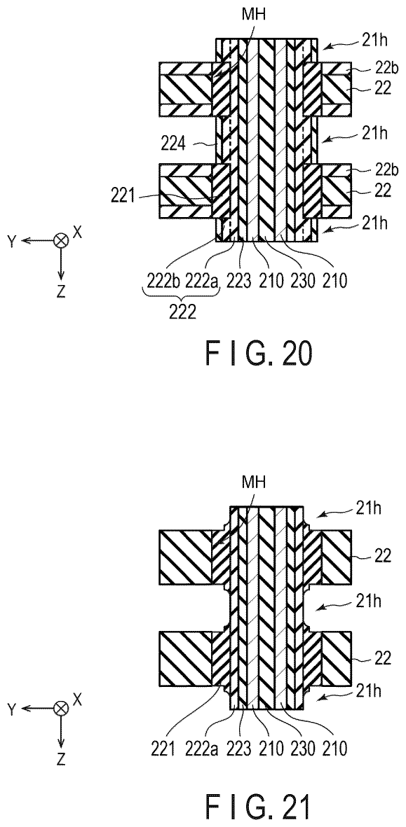

Next, as illustrated in FIG. 20, a block insulation layer 224 is formed on the charge trapping film 222b.

Next, block insulation layers 21a (e. g., insulation layers such as an aluminum oxide film) and barrier films 21b (e.g., a layered film of titanium nitride and titanium, or a single layer film) are deposited on inner walls of spaces 21h by using an ALD method or a CVD method. Additionally, inward the conductive films 21 (e.g., tungsten) are inside the barrier films 21b. By such a replacement step, the sacrificial films 21s are replaced with the conductive films 21. This provides a structure illustrated in FIG. 7. In the slits ST, a silicon oxide film (material) is embedded, or, in some examples, a silicon oxide film along with a metallic material therein may be embedded for making electrical connections or the like.

Thereafter, the vias 28, the wires 24, and the like in FIG. 1 are formed, and thus an array chip 2 is completed. Aside from the array chip 2, a CMOS chip 3 is formed. The array chip 2 and the CMOS chip 3 are bonded together on a bonding surface B1. Additionally, a metal layer 40, a bonding pad 50, and the like are formed, and thus the semiconductor memory device 1 is completed.

When each of the memory holes MH is formed, an inner wall surface of the memory hole MH is a boundary between the cover insulation layers 221 and the insulation films 22. Accordingly, a diameter of the memory hole MH may be considered as a diameter of the boundary between the cover insulation layers 221 and the insulation films 22. In contrast, as illustrated in FIG. 6, the conductive films 21, the barrier films 21b, and the block insulation layers 21a formed in the spaces 21h protrude from the boundary between the cover insulation layers 221 and the insulation films 22 toward a center Cmh of the memory hole MH. In this case, as illustrated in FIG. 20, the spaces 21h can be kept large in the replacement step, so that the material for forming the conductive films 21 can be easily embedded into the spaces 21h. Therefore, it is possible to reduce intervals between adjacent memory holes MH. As a result, a cell size of the memory cell array 2m can be reduced.

For the semiconductor memory device according to the third embodiment, all the insulation films 22 need only comprise insulation films 22b (e.g., SiOC films) in the step described with reference to FIG. 14. Other steps for the third embodiment may be the same as in the first embodiment.

For the semiconductor memory device according to the fourth embodiment, in the step described with reference to FIG. 14, all the insulation films 22 need only comprise insulation films 22b (e.g., SiOC films). Additionally, the insulation films 22b need only be partially oxidized. Other steps for the fourth embodiment may be the same as in the first embodiment.

For the semiconductor memory device according to the fifth embodiment, in the step described with reference to FIG. 16, it is only required to omit the charge trapping film 222a (the seed of the charge trapping film 222b) and to form the seed insulation film 223a. In this case, although there is no seed of the charge trapping film 222b illustrated in FIG. 18 and FIG. 19, the seed insulation film 223a illustrated in FIG. 10 is to be provided instead. Other steps for the fifth embodiment may be the same as in the first embodiment.

For the semiconductor memory device according to the sixth embodiment, in the step described with reference to FIG. 18, the cover insulation layers 221 on the charge trapping film 222a in the spaces 21h are not completely removed, and parts of the cover insulation layers 221 are left. FIG. 21 is a cross-sectional view illustrating an example of a method for producing the semiconductor memory device according to the sixth embodiment. As illustrated in FIG. 21, in etching of the cover insulation layers 221, the cover insulation layers 221 are first removed at center portions in the Z direction of the spaces 21h. The etching is stopped in a state where the cover insulation layers 221 are left at edge portions in the Z direction of the spaces 21h. Thereafter, through the step illustrated in FIG. 19 and the subsequent steps, a structure illustrated in FIG. 11 is provided. Other steps for the sixth embodiment may be the same as in the first embodiment.

For the semiconductor memory device according to the seventh embodiment, in the step described with reference to FIG. 16, each of the cover insulation layers 221 need only be formed as a layered film including insulation layers 221a and 221b that are made of materials different from each other. Other steps for the seventh embodiment may be the same as in the first embodiment.

### Ninth Embodiment

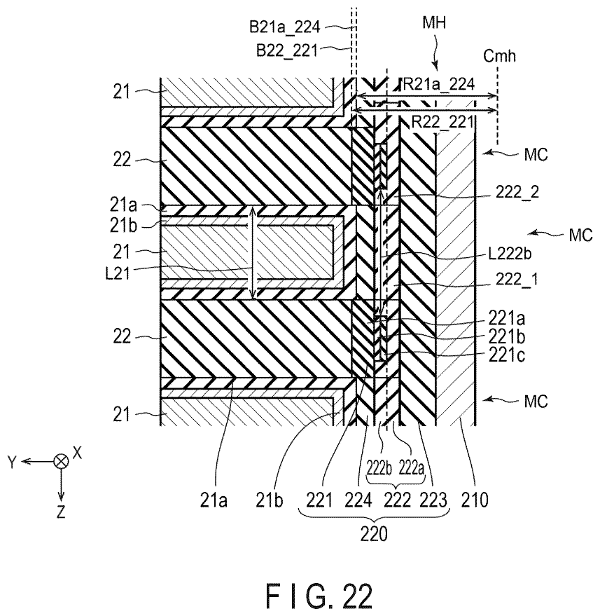

FIG. 22 is a schematic cross-sectional view depicting a memory cell array according to a ninth embodiment. In the ninth embodiment, cover insulation layers 221 are a layered film comprising insulation layers 221a, 221b, and 221c. The insulation layer 221b is sandwiched between the insulation layer 221a and the insulation layer 221c and is made of a material different from materials of the insulation layers 221a and 221c. For example, as the insulation layer 221b, Al₂O₃, HfO, or the like is used. As the insulation layers 221a and 221c, for example, SiO₂, HfO, Zro, or the like is used. As a charge trapping film 222, for example, a silicon nitride film is used.

The insulation layers 221b and 221c are short in length in the Z direction compared with the insulation layer 221a. Both side surfaces in the Z direction of the insulation layer 221a are in contact with block insulation layers 224. In contrast, both side surfaces in the Z direction of the insulation layers 221b and 221c are in contact with charge trapping films 222b (first portions 222_1).

A dimension in the Z direction (a thickness) of a conductive film 21, barrier films 21b, and block insulation layers 21a is equal to or less than a dimension in the Z direction of the charge trapping films 222b. This enables the charge trapping film 222 to accumulate more electric charge.

Between a plurality of charge trapping films 222b adjacent in the Z direction, insulation layers 221b having a relative permittivity higher than a relative permittivity of the charge trapping films 222b are provided.

The rest of the configuration of the ninth embodiment may be the same as in the first embodiment. Therefore, the ninth embodiment can provide the same effects as the first embodiment. In addition, the ninth embodiment may be combined with any one of the second to sixth embodiments. This enables the ninth embodiment to provide the effects of any one of the second to sixth embodiments.

### Tenth Embodiment

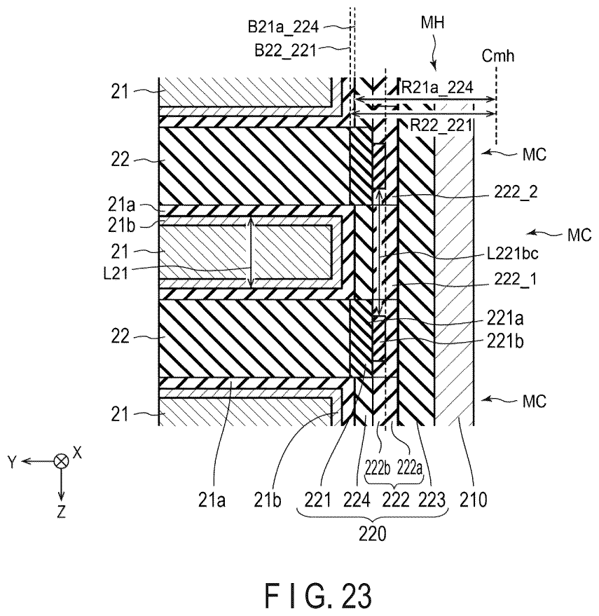

FIG. 23 is a schematic cross-sectional view depicting a memory cell array according to a tenth embodiment. In the tenth embodiment, cover insulation layers 221 are each a layered film of insulation layers 221a and 221b. The insulation layer 221b is sandwiched between the insulation layer 221a and a charge trapping film 222a. The insulation layer 221b is made of a material different from a material of the insulation layer 221a. The insulation layer 221b is formed of a material having a relative permittivity higher than the relative permittivities of the insulation layer 221a and a charge trapping film 222. For example, materials of the insulation layers 221a and 221b may be the same as those in the ninth embodiment.

The insulation layer 221b is short in the Z direction dimension as compared with the insulation layer 221a. Both side surfaces in the Z direction of the insulation layer 221a are in contact with block insulation layers 224. Both side surfaces in the Z direction of the insulation layer 221b are in contact with charge trapping films 222b.

Between charge trapping films 222b adjacent in the Z direction, insulation layers 221b having a relative permittivity higher than the relative permittivity of the charge trapping films 222b are provided.

The rest of the configuration of the tenth embodiment may be the same as in the first embodiment. Therefore, the tenth embodiment can provide the same effects as the first embodiment. In addition, the tenth embodiment may be combined with any one of the second to sixth embodiments. This enables the tenth embodiment to provide the effects of any one of the second to sixth embodiments.

Next, a method for producing according to the ninth embodiment will be described.

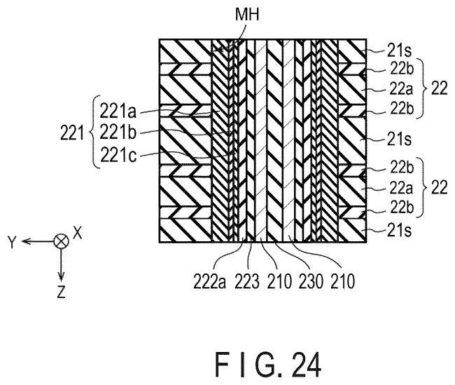

FIG. 24 to FIG. 28 are cross-sectional views illustrating an example of a method for producing the semiconductor memory device according to the ninth embodiment.

First, the steps described with reference to FIG. 14 and FIG. 15 are performed.

Next, as illustrated in FIG. 24, a cover insulation layer 221 is deposited on an inner wall of each of memory holes MH by using an atomic layer deposition (ALD) method or a CVD method. At this time, the cover insulation layer 221 is deposited on the inner wall of the memory hole MH in order of insulation layers 221a, 221b, and 221c.

Next, a charge trapping film 222a and the like are deposited on the inner wall of the memory hole MH as in the first embodiment.

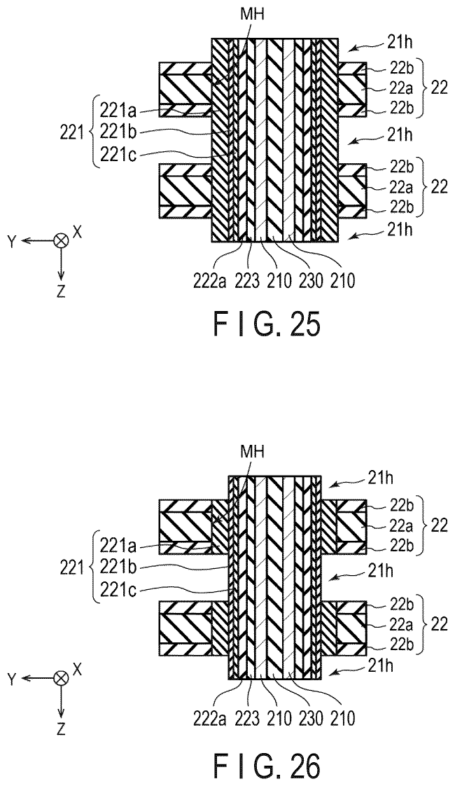

Next, the method proceeds to a step of replacing sacrificial films 21s. As illustrated in FIG. 25, the sacrificial films 21s are selectively etched to be removed using a solution or gas that comprises phosphoric acid or the like. The removal of the sacrificial films 21s is executed via slits ST (see FIG. 2) formed in the stacked body 20. This exposes the insulation layer 221a in spaces 21h after the sacrificial films 21s are removed.

Next, as illustrated in FIG. 26, the insulation layer 221a is isotropically etched. This selectively removes the insulation layer 221a exposed in the spaces 21h. At this time, the insulation layer 221b functions as an etching stopper. Note that the processing executed in the spaces 21h is executed via the slits ST described above.

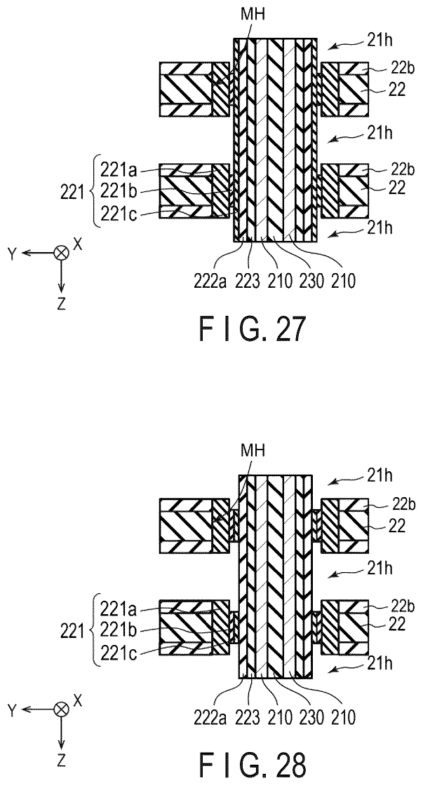

Next, as illustrated in FIG. 27, the insulation layer 221b is isotropically etched. This removes the insulation layer 221b exposed in the spaces 21h. At this time, the insulation layer 221c functions as an etching stopper (etch stop). Insulation layers 221b resulting from the etching are recessed in the Z direction and shorter than insulation layers 221a in the Z direction dimension.

Additionally, as illustrated in FIG. 28, the insulation layer 221c is isotropically etched. This removes the insulation layer 221c exposed in the spaces 21h. The insulation layer 221c is etched with the insulation layers 221b used as masks, and insulation layers 221c resulting from the etching are shorter than insulation layers 221a in the Z direction dimension. This removes the cover insulation layer 221 exposed in the spaces 21h, and a charge trapping film 222a is exposed in the spaces 21h.

Thereafter, through the steps described with reference to FIG. 19 and FIG. 20, the semiconductor memory device 1 illustrated in FIG. 22 is completed. Note that, when charge trapping films 222b are selectively grown on the charge trapping film 222a, side surfaces of the insulation layers 221b and 221c are in contact with the charge trapping films 222b.

Note that, by omitting the insulation layers 221c of the cover insulation layer 221, the semiconductor memory device 1 illustrated in FIG. 23 can be formed.

In the ninth embodiment, the cover insulation layer 221 is constituted by a layered film of the insulation layers 221a to 221c. The insulation layer 221b functions as an etching stopper in the etching of the insulation layer 221a. The insulation layer 221c functions as an etching stopper in the etching of the insulation layer 221b.

### Eleventh Embodiment

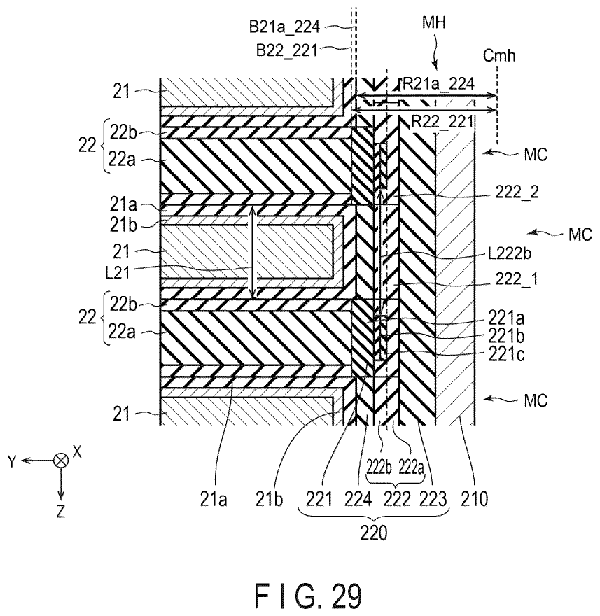

FIG. 29 is a schematic cross-sectional view depicting a memory cell array according to an eleventh embodiment. In the eleventh embodiment, in a structure in FIG. 22, the insulation films 22 are each constituted by a layered film of insulation films 22a and 22b. The insulation film 22a is provided at a center portion of each insulation film 22 and formed of, for example, an insulation material such as a silicon oxide film. The insulation films 22b are provided on both sides of the insulation film 22a in such a manner as to sandwich the insulation film 22a in the Z direction. For example, as the insulation films 22b, an insulation material such as SiOC is used.

The rest of the configuration of the eleventh embodiment may be the same as in the ninth embodiment. Therefore, the eleventh embodiment can provide the same effects as the ninth embodiment.

### Configuration First Example of Lower End Portion of Columnar Body

Next, a configuration of a lower end portion of a columnar body CL will be described.

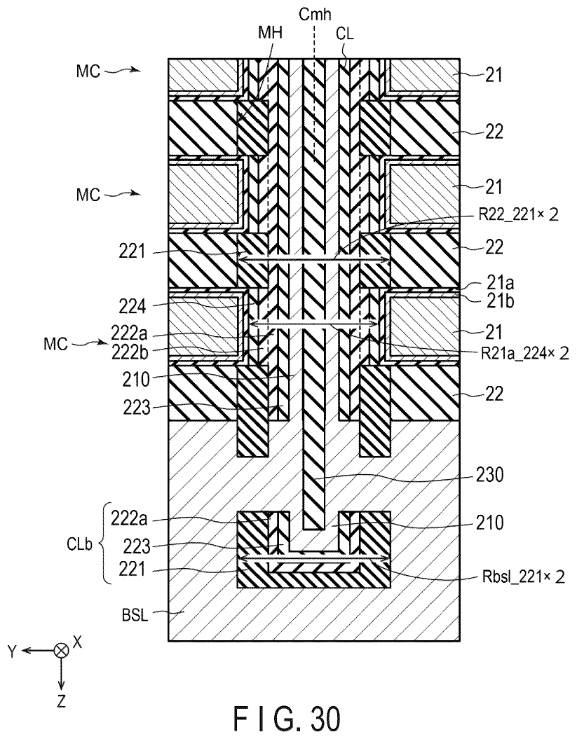

FIG. 30 is a cross-sectional view illustrating a configuration example of a lower end portion CLb of the columnar body CL according to the first embodiment. A configuration of memory cells MC may be the same as that of the memory cells MC in the first embodiment. The lower end portion CLb of the columnar body CL reaches an interior of a source layer BSL. A semiconductor body 210 of columnar bodies CL is electrically connected to the source layer BSL at the lower end portion CLb of the columnar body CL. The source layer BSL is, for example, a doped polysilicon and is directly connected to the semiconductor body 210.

In the configuration first example, a cover insulation layer 221, a charge trapping film 222a, and a tunnel insulation layer 223 are removed in a transverse direction via slits ST to expose the semiconductor body 210. Thereafter, the source layer BSL is formed by embedding a conductive material such as a doped polysilicon via the slits ST.

As mentioned above, the radius R21a_224 of the memory hole MH or the columnar body CL at the boundary B21a_224 in FIG. 6 is equal to or smaller than the radius R22_221 of the memory hole MH or the columnar body CL at the boundary B22_221.

Furthermore, as illustrated in FIG. 30, when a radius of the memory hole MH or the columnar body CL at the lower end portion CLb is denoted by Rbsl_221, the radius R21a_224 is equal to or smaller than the radius Rbsl_221. The columnar body CL is tapered toward the lower end portion CLb. Thus, in at least a memory cell MC closest to the lower end portion CLb, a diameter R21a_224×2 of the columnar body CL is equal to or smaller than a diameter Rbsl_221×2 of an outer circumference of a cover insulation layer 221 at the lower end portion CLb.

A small diameter R21a_224×2 of the columnar body CL in the memory cells MC enables spaces 21h to be kept large in the replacement step. Therefore, it is possible to shorten intervals between a plurality of adjacent memory holes MH, thus leading to reduction of a memory cell array 2m.

The configuration in FIG. 30 can be applied to any one of the second to tenth embodiments.

### Configuration Second Example of Lower End Portion of Columnar Body

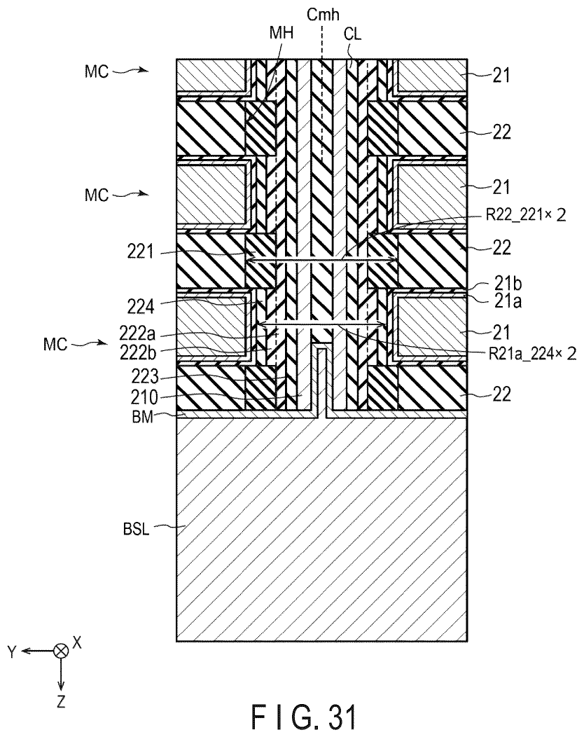

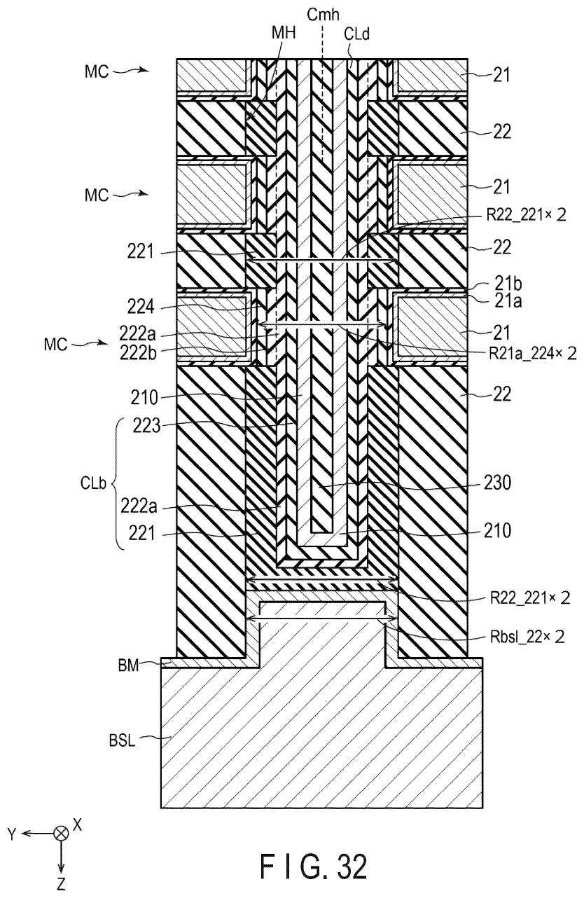

FIG. 31 and FIG. 32 are cross-sectional views illustrating other configuration examples of the lower end portion CLb of the columnar body CL. A configuration of memory cells MC may be the same as that of the memory cells MC in the first embodiment. In a configuration second example, as a source layer BSL, for example, a conductive metallic material such as tungsten is used. As a barrier metal BM, for example, a conductive metal compound such as a layered film of titanium nitride and titanium is used. Note that the barrier metal BM may be regarded as being integrated with the source layer BSL and called the source layer BSL.

A lower end portion of the columnar body CL is removed, and part of a core layer 230 is removed from its lower end portion. The source layer BSL and the barrier metal BM enter into a region of the core layer 230 in a memory hole MH. This electrically connects the semiconductor body 210 to the source layer BSL.

In the configuration second example, a cover insulation layer 221, a charge trapping film 222a, a tunnel insulation layer 223, and the semiconductor body 210 are partially removed from the lower end portion of the columnar body CL, and part of the core layer 230 inside the semiconductor body 210 is etched. This exposes the semiconductor body 210 inside the memory hole MH. Next, the semiconductor body 210 is connected to the barrier metal BM and the source layer BSL inside of the memory hole MH.

Also in the configuration second example, the radius R21a_224 of the memory hole MH or the columnar body CL at the boundary B21a_224 in FIG. 6 is equal to or smaller than the radius R22_221 of the memory hole MH or the columnar body CL at the boundary B22_221.

FIG. 32 is a cross-sectional view illustrating another configuration example of a lower end portion CLb of a dummy columnar body CLd. The dummy columnar body CLd (as a second columnar body) has a configuration basically the same as the configuration of the columnar body CL. However, a semiconductor body 210 is electrically isolated from a source layer BSL below the semiconductor body 210. Accordingly, the dummy columnar body CLd is not used for data storage. That is, unlike the columnar body CL in FIG. 31, a lower end portion of the dummy columnar body CLd is not etched. The source layer BSL is in contact with a cover insulation layer 221.

Also in the dummy columnar body CLd, the radius R21a_224 of the memory hole MH or the columnar body CL at the boundary B21a_224 in FIG. 6 is equal to or smaller than the radius R22_221 of the memory hole MH or the columnar body CL at the boundary B22_221.

Furthermore, as illustrated in FIG. 32, when a radius of a memory hole MH or the dummy columnar body CLd at the lower end portion CLb of the dummy columnar body CLd is denoted by R22_221, the radius R21a_224 is equal to or smaller than the radius R22_221. The dummy columnar body CLd is tapered toward the lower end portion CLb. Thus, in at least a memory cell MC closest to the lower end portion CLb, a diameter R21a_224×2 of the dummy columnar body CLd is equal to or smaller than a diameter R22_221×2 at the lower end portion CLb.

When a radius of a conductive body protruding in a −Z direction immediately below the dummy columnar body CLd (i.e., the source layer BSL and the barrier metal BM) is denoted by Rbsl_22, and a radius of the memory hole MH is equal to Rbsl_22, the diameter R21a_224×2 of the dummy columnar body CLd is equal to or smaller than a diameter Rbsl_22×2 in a memory cell MC closest to the lower end portion CLb.

A small diameter R21a_224×2 of the columnar body CL in the memory cells MC enables spaces 21h to be kept large in the replacement step. Therefore, it is possible to shorten intervals between a plurality of adjacent memory holes MH, thus leading to reduction of a memory cell array 2m.

The configuration in FIG. 32 can be applied to any one of the second to tenth embodiments.

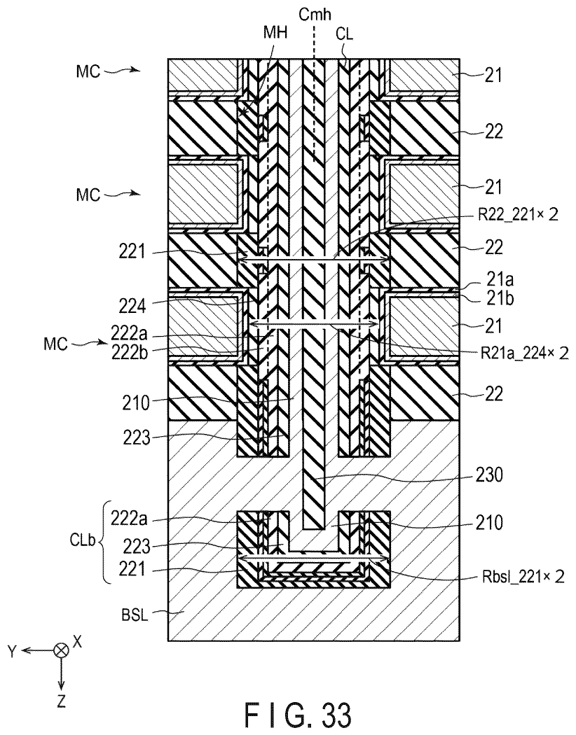

In a case where the configuration first example and the configuration second example of the lower end portion of the columnar body are applied to the ninth embodiment, the lower end portion of the columnar body has configurations illustrated in FIG. 33 to FIG. 35.

### Configuration Third Example of Lower End Portion of Columnar Body

FIG. 33 is a cross-sectional view illustrating a configuration example in which the configuration first example of the lower end portion of the columnar body is applied to the ninth embodiment. In this case, a cover insulation layer 221 is a layered film of insulation layers 221a to 221c. The rest of the configuration of a configuration third example may be the same as in the configuration first example.

### Configuration Fourth Example of Lower End Portion of Columnar Body

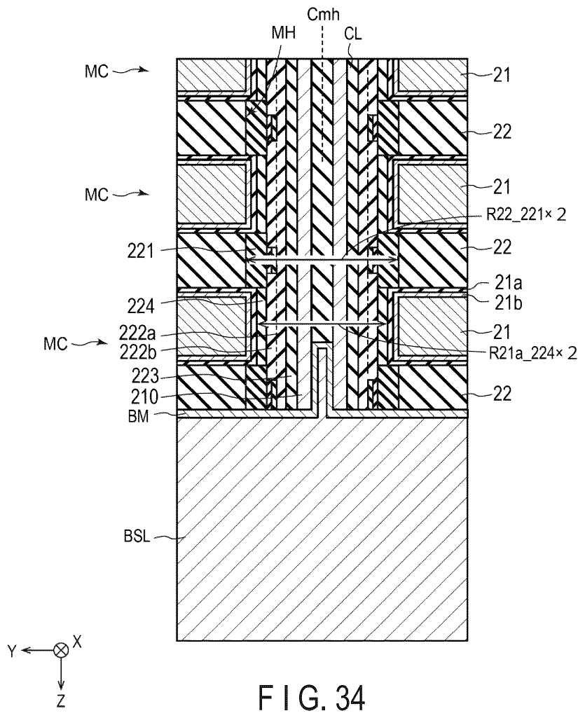

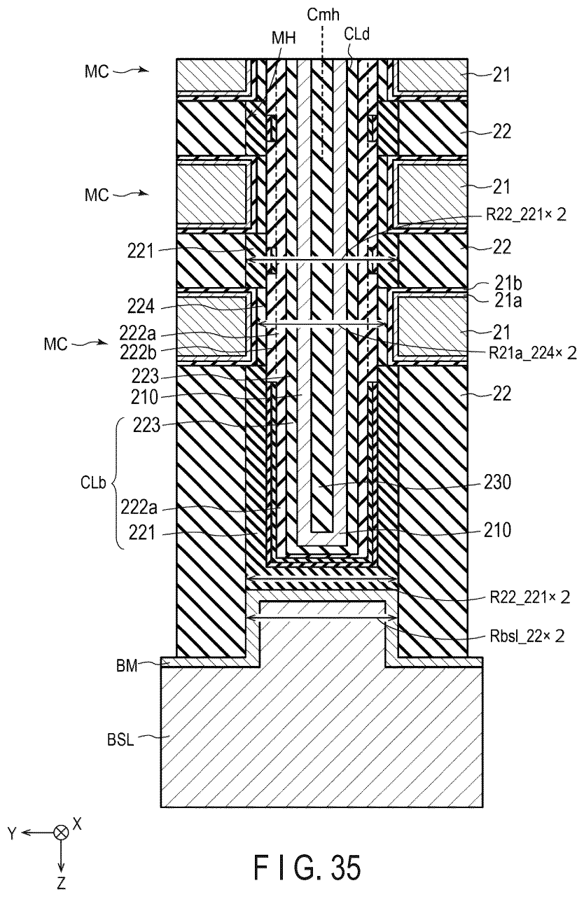

FIG. 34 and FIG. 35 views are cross-sectional illustrating configuration examples of the configuration second example of the lower end portion of the columnar body applied to the ninth embodiment. FIG. 34 illustrates a configuration of a columnar body CL, and FIG. 35 illustrates a configuration of a dummy columnar body CLd. In this case, a cover insulation layer 221 is a layered film of insulation layers 221a to 221c. The rest of the configuration of a configuration example 4 may be the same as in the configuration second example.

Although not illustrated, the configuration first example and the configuration second example may be applied to the tenth embodiment. In this case, a cover insulation layer 221 is a layered film comprising insulation layers 221a and 221b.

### Supplements

(17)

A semiconductor memory device including:
a stacked body that includes a plurality of first conductive films and a plurality of first insulation films alternately stacked in a first direction;
a plurality of first columnar bodies each of which includes a first semiconductor part extending in the first direction in the stacked body, a first insulation part provided between the first semiconductor part and the stacked body, a ninth insulation part provided between the first insulation part and the stacked body, second third insulation parts provided between the ninth insulation part and the plurality of first conductive films, and fourth insulation parts provided between the ninth insulation part and the plurality of first insulation films; and
fifth insulation parts provided between the plurality of first insulation films and the plurality of first conductive films and between the third insulation parts and the plurality of first conductive films and having a relative permittivity higher than the relative permittivities of the first insulation films and the third insulation parts, wherein
the second insulation parts are isolated from one another by the fourth insulation parts in the first direction, and
a diameter of each of the first columnar bodies at a boundary between the fifth insulation part closest to a lower end of the first columnar body and the third insulation part closest to the lower end of the first columnar body is less than or equal to a diameter of an outer circumference of the fourth insulation part at the lower end of the first columnar body.
(18)

The semiconductor memory device according to (17), further including
a second columnar body that has a configuration identical to a configuration of the first columnar bodies and in which the first semiconductor part is not electrically connected to a source layer below the stacked body, wherein
the plurality of first insulation films are each a layered film of a second insulation film and a third insulation film or are each configured with the third insulation film, and
a diameter of the second columnar body at a boundary between one of the fifth insulation parts closest to a lower end portion of the second columnar body and one of the third insulation parts closest to the lower end portion of the second columnar body is equal to or smaller than a diameter of an outer circumference of a conductive body in the source layer, the conductive body protruding in the first direction immediately below the second columnar body.
(19)

The semiconductor memory device according to (17), wherein
a plurality of the third insulation films are provided on both sides of the second insulation film such that the third insulation films sandwich the second insulation film in the first direction, or the third insulation film is provided at a center of a plurality of the second insulation films such that the third insulation film is sandwiched between the second insulation films in the first direction, and
in a cross-section taken in a direction perpendicular to the first direction, a diameter of a boundary between one of the fifth insulation parts and one of the third insulation parts is equal to or smaller than a diameter of a boundary between the first insulation films and the fourth insulation parts.
(20)

The semiconductor memory device according to (17), further including,
a plurality of contacts that penetrate the plurality of first insulation films in contact regions and are connected to the plurality of first conductive films, the contact regions being exposed from the stacked body, the plurality of first conductive films being covered with the plurality of first insulation films, wherein
a plurality of the third insulation films are provided on both sides of the second insulation film such that the third insulation films sandwich the second insulation film in the first direction,
in the contact regions, the third insulation films each include a fourth insulation film between one of the plurality of first conductive films and the second insulation film and a fifth insulation film on the second insulation film,
the fourth insulation film is thicker than the fifth insulation film,
the second insulation part includes first portions provided between the first insulation part and the first conductive films and includes second portions provided between the first insulation part and the first insulation films, the second portions being thinner than the first portions in a second direction that is perpendicular to the first direction, and
in a section in the first direction, a first length of a boundary in the first direction between the first portion and one of the third insulation parts is longer than a second length of the first portion on an extended line of a boundary between the second portion and one of the fourth insulation parts.
(21)

The semiconductor memory device according to (17), further including
a plurality of contacts that penetrate the plurality of first insulation films in contact regions and are connected to the plurality of first conductive films, the contact regions being exposed from the stacked body, the plurality of first conductive films being covered with the plurality of first insulation films, wherein
the third insulation film is provided at a center of a plurality of the second insulation films such that the third insulation film is sandwiched between the second insulation films in the first direction,
the second insulation part includes first portions provided between the first insulation part and the first conductive films and includes second portions provided between the first insulation part and the first insulation films, the second portions being thinner than the first portions in a second direction that is perpendicular to the first direction, and
in a cross-section taken along the first direction, a first length of a boundary in the first direction between the first portion and one of the third insulation parts and a third length of the first portion in the first direction at a boundary between the first portion and the first insulation part are longer than a second length of the first portion on an extended line of a boundary between the second portion and one of the fourth insulation parts.

While certain embodiments have been described, these embodiments have been presented by way of example only, and are not intended to limit the scope of the present disclosure. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the present disclosure.

What is claimed is:

1. A semiconductor memory device, comprising:
a stacked body that includes a plurality of first conductive films and a plurality of first insulation films alternately stacked in a first direction; and
a plurality of first columnar bodies in the stacked body, each first columnar body including:
a first semiconductor part extending in the first direction,
a first insulation part between the first semiconductor part and the stacked body,
a second insulation part between the first insulation part and the stacked body,
third insulation parts between the second insulation part and the first conductive films, and
fourth insulation parts between the second insulation part and the first insulation films, wherein
each second insulation part has first portions between the first insulation part and the first conductive films and second portions between the first insulation part and the first insulation film, and
the second portions are thinner than the first portions in a second direction that is perpendicular to the first direction.

2. The semiconductor memory device of claim 1, wherein each first insulation film is a layered film comprising a second insulation film and a third insulation film.

3. The semiconductor memory device of claim 2, wherein the third insulation film is a silicon oxycarbide film.

4. The semiconductor memory device of claim 1, wherein the first insulation film is a silicon oxycarbide film.

5. The semiconductor memory device of claim 1, further comprising:
fifth insulation parts between the third insulation parts and the first conductive films, the fifth insulation parts having a relative permittivity that is higher than a relative permittivity of the third insulation parts, wherein
a diameter of each of the first columnar bodies at a boundary between the third insulation part closest to a lower end of the first columnar body and the fifth insulation part closest to the lower end of the first columnar body is less than or equal to a diameter of an outer circumference of the fourth insulation part at the lower end of the first columnar body.

6. The semiconductor memory device of claim 1, further comprising:
a second columnar body that has a structural configuration identical to the first columnar bodies, but the first semiconductor part of the second columnar body being electrically isolated from a source layer below the stacked body, wherein
a diameter of the second columnar body at a boundary between the fifth insulation part closest to a lower end of the second columnar body and the third insulation part closest to the lower end of the second columnar body is less than or equal to a diameter of an outer circumference of a conductive body in the source layer that protrudes in the first direction immediately below the second columnar body.

7. The semiconductor memory device of claim 1, further comprising:
fifth insulation parts between the third insulation parts and the first conductive films, the fifth insulation parts having a relative permittivity that is higher than a relative permittivity of the third insulation parts, wherein
in a cross-section taken perpendicular to the first direction, a diameter of the first columnar bodies at a boundary between one of the third insulation parts and one of the fifth insulation parts is less than or equal to a diameter of the first columnar body at a boundary between the first insulation films and the fourth insulation parts.

8. The semiconductor memory device of claim 1, wherein the first insulation film is a layered film comprising a second insulation film and a third insulation film, and second insulation film is sandwiched between a pair of third insulation films in the first direction.

9. The semiconductor memory device of claim 1, further comprising:
a plurality of contacts that penetrate the plurality of first insulation films in contact regions, wherein,
each of the contacts is connected to one of the plurality of first conductive films,
the contact regions extend from the stacked body.

10. A semiconductor memory device, comprising:
a stacked body that includes a plurality of first conductive films and a plurality of first insulation films alternately stacked in a first direction; and
a plurality of first columnar bodies in the stacked body, each first columnar body including:
a first semiconductor part extending in the first direction,
a first insulation part between the first semiconductor part and the stacked body,
a second insulation part between the first insulation part and the stacked body,
third insulation parts between the second insulation part and the first conductive films, and
fourth insulation parts between the second insulation part and the first insulation films, wherein
each second insulation part has first portions between the first insulation part and the first conductive films in a second direction that is perpendicular to the first direction and second portions between the first insulation part and the first insulation films in the second direction,
the second portions are thinner than the first portions in the second direction, and
in a cross-section taken along the first direction, a first length along the first direction of a boundary between a first portion of the second insulation part and one of the third insulation parts is longer than a second length of an extended line along the first direction between adjacent fourth insulation parts.

11. The semiconductor memory device of claim 10, wherein, in a cross-section taken along the first direction, a dimension of the second insulation part along the first direction at a boundary between the first portion and the first insulation part is greater than a minimum distance between adjacent fourth insulation parts along the first direction.

12. A semiconductor memory device, comprising:
a stacked body that includes a plurality of first conductive films and a plurality of first insulation films alternately stacked in a first direction; and
a plurality of first columnar bodies in the stacked body, each first columnar body including:
a first semiconductor part extending in the first direction,
a first insulation part between the first semiconductor part and the stacked body,
a second insulation part between the first insulation part and the stacked body,
third insulation parts between the second insulation part and the first conductive films, and
fourth insulation parts between the second insulation part and the first insulation films, wherein
each second insulation part has first portions between the first insulation part and the first conductive films and second portions between the first insulation part and the first insulation films,
the second portions of the second insulation part are thinner than the first portions of second insulation part in a second direction that is perpendicular to the first direction, and
the fourth insulation parts each include a sixth insulation part and a seventh insulation part that are stacked in the second direction, and
the sixth insulation part and the seventh insulation part being different materials.

13. The semiconductor memory device of claim 12, wherein each first insulation film is a layered film comprising a second insulation film and a third insulation film.

14. The semiconductor memory device of claim 12, further comprising:
fifth insulation parts between the third insulation parts and the first conductive films, the fifth insulation parts having a relative permittivity that is higher than a relative permittivity of the third insulation parts, wherein
a diameter of each of the first columnar bodies at a boundary between the third insulation part closest to a lower end of the first columnar body and the fifth insulation part closest to the lower end of the first columnar body is less than or equal to a diameter of an outer circumference of the fourth insulation part at the lower end of the first columnar body.

15. The semiconductor memory device of claim 12, further comprising:
fifth insulation parts between the third insulation parts and the first conductive films, the fifth insulation parts having a relative permittivity that is higher than a relative permittivity of the third insulation parts; and
a second columnar body that has a structural configuration identical to the first columnar bodies, but the first semiconductor part of the second columnar body is not electrically connected to a source layer below the stacked body, wherein
at a position of the first conductive film closest to a lower end of the second columnar body, a diameter of the second columnar body at a boundary between one of the fifth insulation parts and one of the third insulation parts is less than or equal to a diameter of an outer circumference of the fourth insulation part at the lower end of the second columnar body.

16. The semiconductor memory device of claim 12, further comprising:
fifth insulation parts between the third insulation parts and the first conductive films, the fifth insulation parts having a relative permittivity that is higher than a relative permittivity of the third insulation parts, wherein
in a cross-section taken in a direction perpendicular to the first direction, a diameter of a boundary between one of the fifth insulation parts and one of the third insulation parts is less than or equal to a diameter of a boundary between the first insulation films and the fourth insulation parts.

17. The semiconductor memory device of claim 12, wherein
the fourth insulation parts each include sixth and seventh insulation parts that are stacked in the second direction, and
the sixth insulation part and the seventh insulation part are different materials.

18. The semiconductor memory device of claim 12, wherein
the fourth insulation parts each include sixth, seventh, and eighth insulation parts that are stacked in the second direction, and
the sixth and eighth insulation parts and a different material than the seventh insulation part.

19. The semiconductor memory device of claim 12, further comprising:
fifth insulation parts between the first insulation films and the first conductive films and between the third insulation parts and the first conductive films, the fifth insulation parts having a relative permittivity that is higher than the relative permittivities of the first insulation films and the third insulation parts, wherein
a combined dimension of one of the first conductive films and one of the fifth insulation parts along the first direction is less than or equal to a dimension of the first portion of the second insulation part along the first direction.

20. The semiconductor memory device of claim 12, wherein the seventh insulation part is in contact with the first portion of the second insulation part along the first direction.
